(19) United States
(12) Patent Application Publication
(10) Pub. No.: US 2006/0031616 A1
(43) Pub. Date: Feb. 9, 2006

(54) Wireless transmission multimedia device

(75) Inventor: Chi-Lin Chuang, Taipei (TW)

Correspondence Address: MADSON & METCALF;GATEWAY TOWER WEST, SUITE 900, 15 WEST SOUTH TEMPLE, SALT LAKE CITY, UT, 84101, US

(73) Assignee: Apacer Technology, Inc.

(21) Appl. No.: 11/178,844

(22) Filed: Jul. 11, 2005

(30) Foreign Application Priority Data
Aug. 4, 2004 (TW) 093123383

(51) Int. Cl. H05K 7/10

(52) U.S. Cl. 710/301; 700/94; 455/3.01

(57) ABSTRACT

A wireless transmission multimedia device includes a peripheral component unit, a processor, a controller, an ultra-wideband (UWB) controller and a decoder. The processor is electrically connected to the peripheral component unit for executing an instruction from the peripheral component unit. The controller is electrically connected to the processor, and issues a control signal according to execution of the instruction. The UWB controller is electrically connected to the controller, and wirelessly communicated with an external UWB interface. In response to the control signal, a data file is controlled to exchange between the UWB controller and the external UWB interface. The decoder is electrically connected to the controller for decoding the data file into a digital signal.

### FIELD OF THE INVENTION

The present invention relates to a multimedia device, and more particularly to a wireless transmission multimedia device.

### BACKGROUND OF THE INVENTION

With digitalized trend, many consumable electronic products are developed to integrate high-quality digital audio/video contents into diverse apparatuses. In this generation, a multimedia device is one of the well-established consumable electronic products. With the user's requirement, favorite songs are stored in the memory unit of the multimedia device. Alternatively, voice data are converted into audio/video files, which are stored into the memory unit.

Generally, the multimedia device uses a universal serial bus (USB) as a transmission interface. The representative multimedia device includes a portable hard disc, a MP3 player, etc.

Take a MP3 player for example. The commercially available MP3 player has a memory unit electrically connected to a USB client port. The favorite songs in a MP3 format can be stored in the memory unit. By means of the MP3 player, the MP3-format songs will be decoded into digital audio signals for play. In a case that the MP3-format songs are intended to refresh, a transmission wire is required to interconnect the USB client port of the MP3 player with a USB port of a personal computer, and then the MP3-format songs having been stored in the hard disc of the personal computer will be downloaded into the memory unit of the MP3 player so as to implement the refreshing operation. In order to achieve resource sharing functions, the audio files or songs included in the MP3 player can be transmitted to the personal computer and stored therein. When another multimedia device is in communication with the personal computer, the MP3-format songs stored in the personal computer will be played via this multimedia device.

Take a portable hard disc for example. The commercially available portable hard disc has a flash memory electrically connected to a USB client port. The flash memory is employed for storing files therein. In a case that the files are intended to access, a transmission wire is required to interconnect the USB client port of the portable hard disc with a USB port of a personal computer. In such manner, the files having been stored in the hard disc of the personal computer will be downloaded into the flash memory of the portable hard disc. Alternatively, the files included in the portable hard disc can be transmitted to the personal computer. When another multimedia device is in communication with the personal computer, the files stored in the personal computer will be transmitted to this multimedia device so as to achieve resource sharing functions.

As previously described, a transmission wire is required to interconnect the multimedia device with a personal computer such that the files included in the multimedia device can be transmitted to the personal computer and stored therein, or the files stored in the personal computer can be downloaded into another multimedia device via the transmission wire. In other words, data exchange between one multimedia device and another multimedia device should be implemented via an intermediary personal computer. Since data fail to be directly transmitted from one multimedia to another multimedia, this approach is not user-friendly.

In views of the above-described disadvantages, the applicant keeps on carving unflaggingly to develop a wireless transmission multimedia device according to the present invention through wholehearted experience and research.

### SUMMARY OF THE INVENTION

An object of the present invention is to provide a wireless transmission multimedia device for implementing data exchange and resource sharing without using the intermediary personal computer.

In accordance with a first aspect of the present invention, there is provided a wireless transmission multimedia device. The wireless transmission multimedia device comprises a peripheral component unit, a processor, a controller, an ultra-wideband (UWB) controller and a decoder. The processor is electrically connected to the peripheral component unit for executing an instruction from the peripheral component unit. The controller is electrically connected to the processor, and issues a control signal according to execution of the instruction. The UWB controller is electrically connected to the controller, and wirelessly communicated with an external UWB interface. In response to the control signal, a data file is controlled to exchange between the UWB controller and the external UWB interface. The decoder is electrically connected to the controller for decoding the data file into a digital signal.

In an embodiment, the peripheral component unit comprises a key pad and a display unit. The key pad is electrically connected to the processor for generating a triggering signal when the key pad is pressed down. The display unit is used for displaying the content associated with the triggering signal therevia.

In an embodiment, the display unit is a liquid crystal display.

In an embodiment, the peripheral component unit further comprises a read-only memory (ROM) and a register. The read-only memory (ROM) is electrically connected to the processor for storing system program instructions and data required for operating the multimedia device. The register is electrically connected to read-only memory (ROM) for temporarily storing the system program instructions and data required for operating the multimedia device.

In an embodiment, the register is a random access memory (RAM).

In an embodiment, the data file is in a MP3 format.

In an embodiment, the decoder is a MP3 decoder for decoding the data file into the digital signal in a MP3 format.

In an embodiment, the wireless transmission multimedia device further comprises a power supply unit for providing power required for the multimedia device.

In an embodiment, the power supply unit comprises a battery provides an AC voltage. The AC/DC converter is electrically connected to the battery for converting the AC voltage into a DC voltage required for the multimedia device.

In accordance with a second aspect of the present invention, there is provided a wireless transmission multimedia device. The wireless transmission multimedia device comprises a peripheral component unit, a processor, a controller, an ultra-wideband (UWB) controller and a storage medium. The processor is electrically connected to the peripheral component unit for executing an instruction from the peripheral component unit. The controller is electrically connected to the processor, and issues a control signal according to execution of the instruction. The UWB controller is electrically connected to the controller, and wirelessly communicated with an external UWB interface. In response to the control signal, a data file is controlled to exchange between the UWB controller and the external UWB interface. The storage medium is electrically connected to the controller for storing the data file.

In an embodiment, the data file is transmitted from the controller in a USB format, and the data file is stored in the storage medium in a peripheral component interconnect (PCI) format.

In an embodiment, the wireless transmission multimedia device further comprises a bridge device electrically connected between the controller and the storage medium for converting the USB-format data file into the PCI-format data file.

In an embodiment, the storage medium is a flash memory.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic circuit configuration of a wireless transmission multimedia device according to a first preferred embodiment of the present invention; and

FIG. 2 is a schematic circuit configuration of a wireless transmission multimedia device according to a second preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

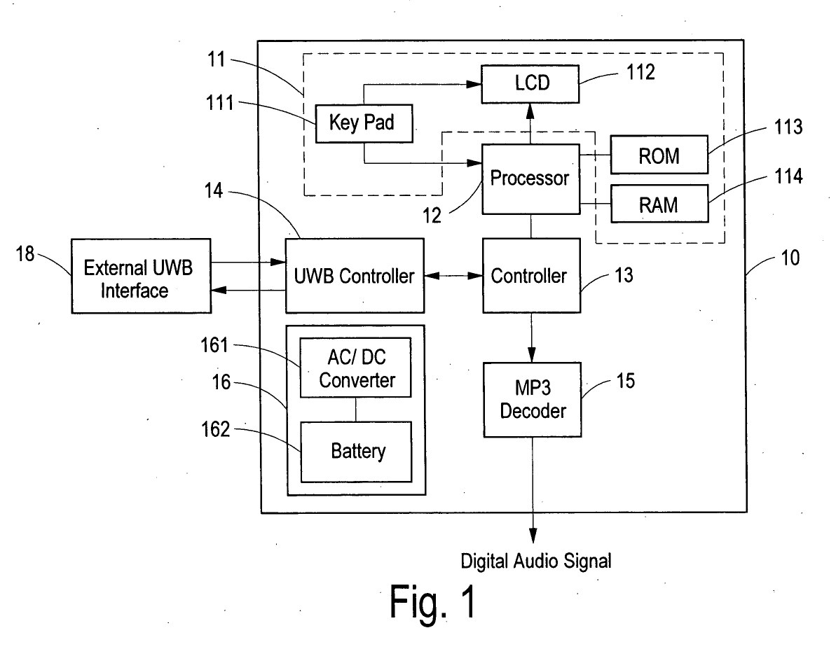

Referring to FIG. 1, a schematic circuit configuration of a wireless transmission multimedia device according to a first preferred embodiment of the present invention is shown. The multimedia device 10 is a MP3 (MPEG Audio Layer3) player, and comprises a peripheral component unit 11, a processor 12, a controller 13, an ultra-wideband (UWB) controller 14, a decoder 15 and a power supply unit 16.

The peripheral component unit 11 is electrically connected to the processor 12, and comprises a key pad 111, a display unit 112 such as a small-sized liquid crystal display (LCD), a read-only memory (ROM) 113 and a register 114 such as a random access memory (RAM).

The key pad 111 is electrically connected to the processor 12 and the liquid crystal display 112. When the key pad 111 is pressed down, a corresponding triggering signal is issued from the key pad 111 to the processor 12 and the liquid crystal display 112. In response to the triggering signal, the processor 12 will perform a corresponding operation. The content associated with the triggering signal is displayed via the liquid crystal display 112. The read-only memory 113 is electrically connected to the processor 12 for storing system program instructions and data required for operating the MP3 player 10. The instructions and data stored in the read-only memory 113 can be read from the processor 12 as required. The random access memory (RAM) 114 is electrically connected to the processor 12 for temporarily storing the instructions and data required to operate the MP3 player 10. The processor 12 can read or write data into/from the random access memory (RAM) 114.

The controller 13 is electrically connected to the processor 12 for controlling data exchange between the UWB controller 14 and an external UWB interface 18. The UWB controller 14 is a wireless interface operated according to a UWB protocol. In response to a control signal issued from the controller 13, the MP3 player 10 of the present invention can be wirelessly communicated with at least one external UWB interface 18. On one hand, in response to the control signal issued from the controller 13, the data file stored in the external UWB interface 18 can be transmitted to the MP3 player 10 via the UWB controller 14. On the other hand, in response to the control signal issued from the controller 13, the data file stored in the external UWB interface 18 can be shared with other external UWB interface (not shown). Since the MP3 player 10 of the present invention is communicated with the external UWB interface 18 via the UWB controller 14, no additional intermediary personal computer is required on condition that the external UWB interface 18 is disposed within the wireless transmission area of the UWB controller 14.

In some embodiments, an exemplary decoder 15 is a MP3 decoder, which is electrically connected to the controller 13. By means of the MP3 decoder 15, the data file transmitted from the external UWB interface 18 will be decoded into digital audio signals in a MP3 format and outputted to play.

The power supply unit 16 comprises an AC/DC converter 161 and a battery 162. By means of the AC/DC converter 161, an AC voltage from the battery 162 is converted into a DC voltage, which is required for operating the MP3 player 10.

Since the MP3 player 10 of the present invention is communicated with the external UWB interface 18 via the UWB controller 14, no additional intermediary personal computer is required, and thus the MP3 player 10 of the present invention is more user-friendly than that of prior art.

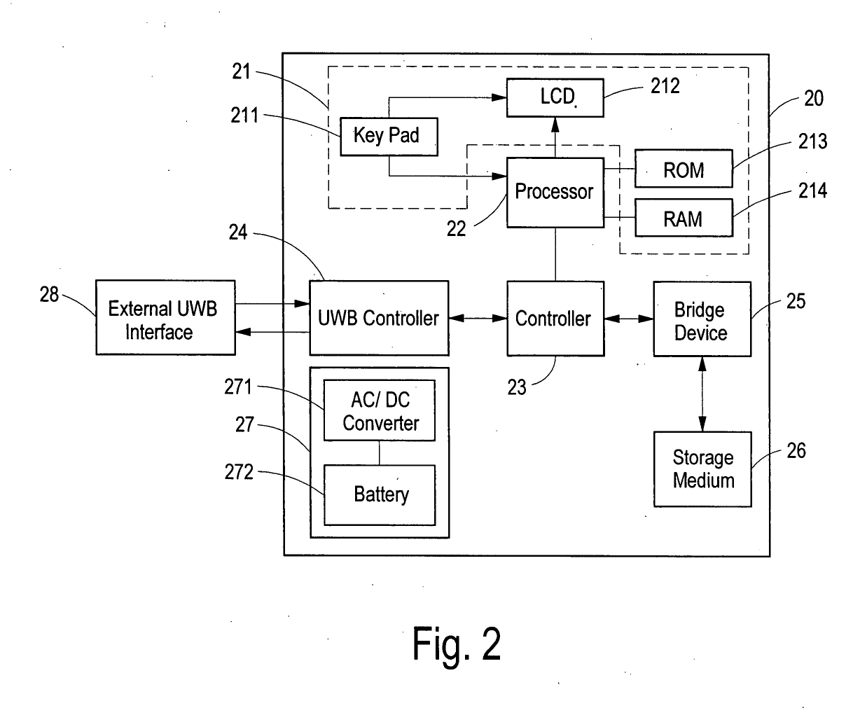

Referring to FIG. 2, a schematic circuit configuration of a wireless transmission multimedia device according to a second preferred embodiment of the present invention is shown. The multimedia device 20 is a portable hard disc, and comprises a peripheral component unit 21, a processor 22, a controller 23, an ultra-wideband (UWB) controller 24, a bridge device 25, a storage medium 26 and a power supply unit 27.

The peripheral component unit 21 is electrically connected to the processor 22, and comprises a key pad 211, a liquid crystal display 212, a read-only memory (ROM) 213 and a random access memory (RAM) 214. The power supply unit 27 comprises an AC/DC converter 271 and a battery 272. By means of the AC/DC converter 271, an AC voltage from the battery 272 is converted into a DC voltage, which is required for operating the portable hard disc 20.

The operation principles of the peripheral component unit 21, the processor 22, the controller 23, the UWB controller 24 and the power supply unit 27 are similar to those described above, and are not intended to be described redundantly herein.

The storage medium 26 of the portable hard disc 20 is electrically connected to the controller 23 via the bridge device 25. The storage medium 26 can be employed to store data file of the portable hard disc 20. Alternatively, the data file from at least one external UWB interface 28 can be transmitted to the portable hard disc 20 and stored in the storage medium 26. In some embodiments, the storage medium 26 includes but is not limited to a flash memory.

In some embodiments, the data file is transmitted from the controller 23 in a USB format, while the data file is stored in the storage medium 26 in a peripheral component interconnect (PCI) format. The bridge device 25 is electrically connected between the controller 23 and the storage medium 26 such that the USB-format data file from the controller 23 is converted into the PCI-format data file to be stored in the storage medium 26. On the other hand, via the bridge device 25, the PCI-format data file stored in the storage medium 26 can be converted into the USB-format data file to be transmitted to the controller 23.

In the above embodiments, the controller 13 and 23 are preferably Ali-5273 control chips commercial available from Ali Corporation, Taiwan. Examples of the processor 12 and 22 include the AM1-2880 from Texas Instruments Inc.

From the above description, the wireless transmission multimedia device of the present invention is capable of implementing data exchange and resource sharing via the UWB wireless interface without using the intermediary personal computer. The storage medium can be employed to store data file of the portable hard disc or from at least one external UWB interface. Moreover, the wireless transmission multimedia device of the present invention can perform data exchange between a plurality of external UWB interfaces. Therefore, the wireless transmission multimedia device of the present invention is more flexible and user-friendly.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wireless transmission multimedia device comprising:
a peripheral component unit;
a processor electrically connected to said peripheral component unit for executing an instruction from said peripheral component unit;
a controller electrically connected to said processor, and issuing a control signal according to execution of said instruction;
an ultra-wideband (UWB) controller electrically connected to said controller, wirelessly communicated with an external UWB interface, and in response to said control signal, controlling a data file to be exchanged between said UWB controller and said external UWB interface; and
a decoder electrically connected to said controller for decoding said data file into a digital signal.

2. The wireless transmission multimedia device according to claim 1 wherein said peripheral component unit comprises:
a key pad electrically connected to said processor for generating a triggering signal when said key pad is pressed down; and
a display unit for displaying the content associated with said triggering signal therevia.

3. The wireless transmission multimedia device according to claim 2 wherein said display unit is a liquid crystal display.

4. The wireless transmission multimedia device according to claim 2 wherein said peripheral component unit further comprises:
a read-only memory (ROM) electrically connected to said processor for storing system program instructions and data required for operating said wireless transmission multimedia device; and
a register electrically connected to said read-only memory (ROM) for temporarily storing said system program instructions and data required for operating said wireless transmission multimedia device.

5. The wireless transmission multimedia device according to claim 4 wherein said register is a random access memory (RAM).

6. The wireless transmission multimedia device according to claim 1 wherein said data file is in a MP3 format.

7. The wireless transmission multimedia device according to claim 6 wherein said decoder is a MP3 decoder for decoding said data file into said digital signal in a MP3 format.

8. The wireless transmission multimedia device according to claim 1 further comprising a power supply unit for providing power required for said wireless transmission multimedia device.

9. The wireless transmission multimedia device according to claim 8 wherein said power supply unit comprises:
a battery for providing an AC voltage; and
an AC/DC converter electrically connected to said battery for converting said AC voltage into a DC voltage required for said wireless transmission multimedia device.

10. A wireless transmission multimedia device comprising:
a peripheral component unit;
a processor electrically connected to said peripheral component unit for executing an instruction from said peripheral component unit;
a controller electrically connected to said processor, and issuing a control signal according to execution of said instruction;
an ultra-wideband (UWB) controller electrically connected to said controller, wirelessly communicated with an external UWB interface, and in response to said control signal, controlling a data file to be exchanged between said UWB controller and said external UWB interface; and
a storage medium electrically connected to said controller for storing said data file.

11. The wireless transmission multimedia device according to claim 10 wherein said peripheral component unit comprises:
a key pad electrically connected to said processor for generating a triggering signal when said key pad is pressed down; and
a display unit for displaying the content associated with said triggering signal therevia.

12. The wireless transmission multimedia device according to claim 11 wherein said display unit is a liquid crystal display.

13. The wireless transmission multimedia device according to claim 11 wherein said peripheral component unit further comprises:
a read-only memory (ROM) electrically connected to said processor for storing system program instructions and data required for operating said wireless transmission multimedia device; and
a register electrically connected to read-only memory (ROM) for temporarily storing said system program instructions and data required for operating said wireless transmission multimedia device.

14. The wireless transmission multimedia device according to claim 13 wherein said register is a random access memory (RAM).

15. The wireless transmission multimedia device according to claim 10 wherein said data file is transmitted from said controller in a USB format, and said data file is stored in said storage medium in a peripheral component interconnect (PCI) format.

16. The wireless transmission multimedia device according to claim 15 further comprising a bridge device electrically connected between said controller and said storage medium for converting said USB-format data file into said PCI-format data file.

17. The wireless transmission multimedia device according to claim 10 wherein said storage medium is a flash memory.

18. The wireless transmission multimedia device according to claim 10 further comprising a power supply unit for providing power required for said wireless transmission multimedia device.

19. The wireless transmission multimedia device according to claim 18 wherein said power supply unit comprises:
a battery for providing an AC voltage; and
an AC/DC converter electrically connected to said battery for converting said AC voltage into a DC voltage required for said wireless transmission multimedia device.
